(19) United States
(12) Patent Application Publication
(10) Pub. No.: US 2023/0253427 A1
(43) Pub. Date: Aug. 10, 2023

(54) SEMICONDUCTOR PACKAGE AND METHOD FOR MANUFACTURING SEMICONDUCTOR PACKAGE

(71) Applicant: SONY SEMICONDUCTOR SOLUTIONS CORPORATION, KANAGAWA (JP)

(72) Inventors: YOSHIAKI MASUDA, KANAGAWA (JP); TOKIHISA KANEGUCHI, KANAGAWA (JP)

(21) Appl. No.: 18/003,448

(22) PCT Filed: Jun. 23, 2021
(86) PCT No.: PCT/JP2021/023698

§ 371 Date: Dec. 27, 2022

(30) Foreign Application Priority Data
Jul. 7, 2020 (JP) 2020-116831

(51) Int. Cl. H01L 27/146

(52) U.S. Cl. CPC H01L 27/14627; H01L 27/14621; H01L 27/14685; H01L 27/14636; H01L 27/14687; H01L 27/14632

(57) ABSTRACT

The present technology relates to a semiconductor package and a method for manufacturing the semiconductor package that are capable of improving the quality of the semiconductor package having a WCSP structure. A semiconductor package includes: a semiconductor substrate including a light receiving element; an on-chip lens disposed on an incident surface side of the semiconductor substrate; a resin layer in contact with a central portion including a most protruding portion of the on-chip lens; and a glass substrate in contact with a surface of the resin layer opposite to a surface of the resin layer in contact with the on-chip lens, wherein a space is provided between a peripheral portion around the central portion of the on-chip lens and the resin layer. The present technology can be applied to, for example, an imaging element.

### TECHNICAL FIELD

The present technology relates to a semiconductor package and a method for manufacturing the semiconductor package, and more particularly to a semiconductor package having a wafer level chip size package (WCSP) structure and a method for manufacturing the semiconductor package.

### BACKGROUND ART

In recent years, electronic devices such as camera-equipped mobile terminal devices and digital cameras have been developed to increase the resolution of the camera and reduce the size and thickness of the camera.

On the other hand, in order to reduce the size and height of imaging elements used in cameras, imaging elements using semiconductor packages having a WCSP structure have been widely used (see PTL 1, for example).

### CITATION LIST

### Patent Literature

[PTL 1]

JP 2008-270650A

### SUMMARY

### Technical Problem

On the other hand, there is a concern that reduced size and height of semiconductor packages may lead to reduced quality.

The present technology has been made in view of such a situation and is intended to improve the quality of a semiconductor package having a WCSP structure.

### Solution to Problem

A semiconductor package according to a first aspect of the present technology includes: a semiconductor substrate including a light receiving element; an on-chip lens disposed on an incident surface side of the semiconductor substrate; a resin layer in contact with a central portion including a most protruding portion of the on-chip lens; and a glass substrate in contact with a surface of the resin layer opposite to a surface of the resin layer in contact with the on-chip lens, wherein a space is provided between a peripheral portion around the central portion of the on-chip lens and the resin layer.

In the first aspect of the present technology, the incident light transmitted through a glass substrate and the resin layer enters the peripheral portion of the on-chip lens through the space provided between the peripheral portion of the on-chip lens and the resin layer.

A method for manufacturing a semiconductor package according to a second aspect of the present technology includes: a coating step of coating a resin on one surface of a glass substrate; a curing step of curing the resin; and a bonding step of bonding a surface of a wafer on which an on-chip lens is formed and the surface of the glass substrate on which the resin is coated.

In the second aspect of the present technology, one surface of the glass substrate is coated with the resin, the resin is cured, and the surface of the wafer on which the on-chip lens is formed and the surface on which the resin of the glass substrate is coated are bonded together.

### BRIEF DESCRIPTION OF DRAWING

FIG. 1 is a cross-sectional view schematically illustrating a configuration example of a semiconductor package having a WCSP structure with cavities.

FIG. 2 is a cross-sectional view schematically illustrating a first configuration example of a semiconductor package having a cavityless WCSP structure.

FIG. 3 includes cross-sectional views schematically illustrating the first configuration example and a second configuration example of the semiconductor package having a cavityless WCSP structure.

FIG. 4 is a block diagram illustrating a schematic configuration example of an electronic device to which the present technology is applied.

FIG. 5 is a block diagram illustrating a schematic configuration example of an imaging element of FIG. 4.

FIG. 6 is a diagram for explaining the basic functions of a unit pixel of FIG. 5.

FIG. 7 is a cross-sectional view schematically illustrating a configuration example of a semiconductor package including the imaging element of FIG. 4.

FIG. 8 is a cross-sectional view schematically illustrating a first configuration example in the vicinity of a boundary between a pixel region and a peripheral region of the semiconductor package of FIG. 7.

FIG. 9 is a cross-sectional view schematically illustrating a second configuration example in the vicinity of a boundary between a pixel region and a peripheral region of the semiconductor package of FIG. 7.

FIG. 10 is a cross-sectional view schematically illustrating a third configuration example in the vicinity of a boundary between a pixel region and a peripheral region of the semiconductor package of FIG. 7.

FIG. 11 is a flowchart for explaining a method for manufacturing the semiconductor package of FIG. 7.

FIG. 12 is a diagram illustrating an application example of an imaging element.

FIG. 13 is a diagram illustrating an example of a schematic configuration of an endoscope surgery system.

FIG. 14 is a block diagram illustrating an example of a functional configuration of a camera head and a CCU.

FIG. 15 is a block diagram illustrating an example of a schematic configuration of a vehicle control system.

FIG. 16 is an explanatory diagram illustrating an example of installation positions of a vehicle exterior information detecting unit and an imaging unit.

### DESCRIPTION OF EMBODIMENTS

Hereinafter, modes for carrying out the present technology will be described. The description will be made in the following order.
1. Background of Present Technology
2. Embodiment
3. Modification Example
4. Application Examples
5. Others

### 1. Background of Present Technology

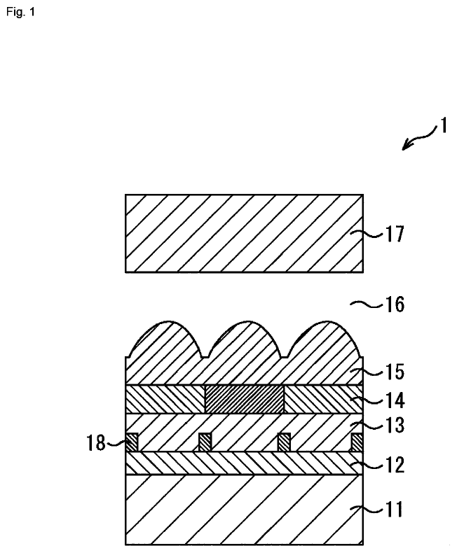

First, the background of the present technology will be described with reference to FIGS. 1 to 3.

FIG. 1 is a cross-sectional view schematically illustrating a configuration example of a semiconductor package 1 having a WCSP structure with cavities and including a backside-illumination type imaging element (image sensor).

In the semiconductor package 1, a semiconductor substrate 11, an insulating film 12, a planarization layer 13, color filters 14, on-chip lenses 15, and a glass substrate 17 are stacked in this order from the bottom in the drawing. A light-shielding film 18 for shielding each pixel from light from adjacent pixels is formed on the planarization layer 13. A space (hereinafter referred to as an air gap) 16 is provided between the on-chip lenses 15 and the glass substrate 17.

The semiconductor package 1 is produced in such a manner that a light-collection structure (the color filters 14 and the on-chip lenses 15) and the like are formed on a wafer made of a semiconductor such as silicon, the glass substrate 17 is then bonded to the wafer, and the wafer is separated into individual pieces.

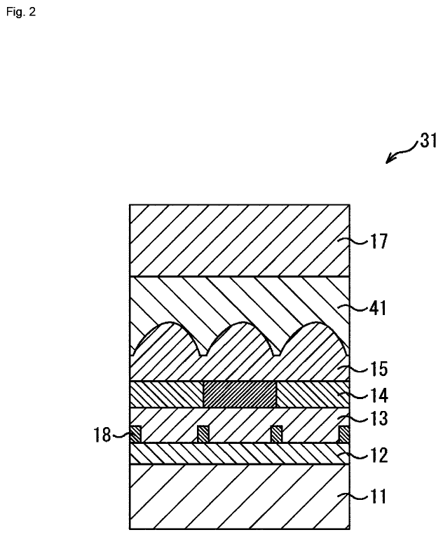

FIG. 2 is a cross-sectional view schematically illustrating a configuration example of a cavityless semiconductor package 31 having a WCSP structure and including a backside-illumination type imaging element. In the drawing, the same reference numerals are given to the units corresponding to the semiconductor package 1 of FIG. 1 and description thereof will be appropriately omitted.

The semiconductor package 31 differs from the semiconductor package 1 in that a resin layer 41 is disposed instead of the air gap 16. In other words, in the semiconductor package 31, a space between the on-chip lenses 15 and the glass substrate 17 is filled with a resin.

As a result, the strength of the semiconductor package 31 is improved and, for example, the thicknesses of the semiconductor substrate 11 and the glass substrate 17 can be reduced, and the size and height of the semiconductor package 31 can be reduced.

In order to further reduce the height of the semiconductor package 31, for example, it is considered to reduce the thickness of the planarization layer 13 or eliminate the planarization layer 13.

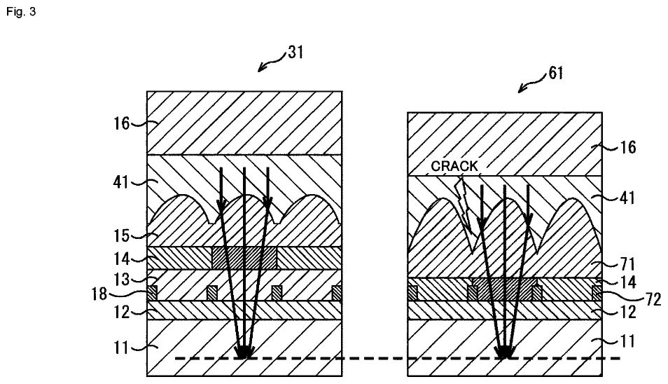

In FIG. 3, configuration examples of the semiconductor package 31 and a semiconductor package 61 in which the planarization layer 13 is eliminated from the semiconductor package 31 are arranged side by side. The horizontal dotted lines on the semiconductor substrate 11 indicate the light collection positions of an on-chip lens 15 and an on-chip lens 71.

The semiconductor package 61 differs from the semiconductor package 31 in that the planarization layer 13 is eliminated and on-chip lenses 71 are provided instead of the on-chip lenses 15. By eliminating the planarization layer 13, a light shielding film 72 for shielding each pixel from light from adjacent pixels is formed in the layer of the color filters 14.

Thus, the height of the semiconductor package 61 can be reduced as compared to the semiconductor package 31.

Meanwhile, by eliminating the planarization layer 13, the distance between the on-chip lenses 15 and the light receiving surface of a photodiode formed on the semiconductor substrate 11 is shortened. Accordingly, in order to make the focal length of each on-chip lens 71 shorter than that of each on-chip lens 15, it is necessary to make the curvature of the on-chip lens 71 larger than that of the on-chip lens 15.

However, as the curvature of each on-chip lens 71 increases, the depth of the gap between the on-chip lenses 71 increases. This leads to an increased film stress of the resin layer 41, and thus cracks are likely to occur in the resin layer 41. In addition, such an increased curvature increases the difficulty of manufacturing the on-chip lens 71. As a result, the quality of the semiconductor package 61 may deteriorate.

The present technology has been made in view of such a situation and is intended to improve the quality of a semiconductor package having a WCSP structure in which a resin layer is provided between an on-chip lens and a glass substrate.

### 2. Embodiment

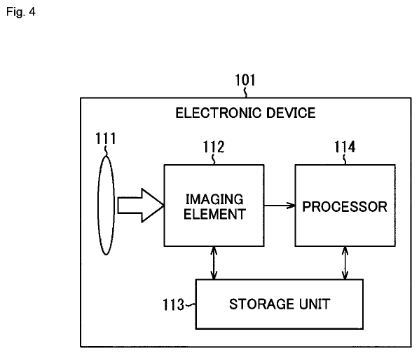

Next, an embodiment of the present technology will be described with reference to FIGS. 4 to 11.

<Configuration Example of Electronic Device>

FIG. 4 is a block diagram illustrating a schematic configuration example of an electronic device 101 to which the present technology is applied. The electronic device 101 includes, for example, an imaging lens 111, a solid-state imaging element 112, a storage unit 113, and a processor 114.

The imaging lens 111 is an example of an optical system that collects incident light and forms an image on the light receiving surface of the imaging element 112. The light-receiving surface is, for example, a surface on which light-receiving elements (for example, photoelectric conversion elements such as photodiodes) provided in the imaging element 112 are arranged. The imaging element 112 performs photoelectric conversion of incident light to generate image data. The imaging element 112 also executes predetermined signal processing such as noise removal or white balance adjustment on the generated image data.

The storage unit 113 includes, for example, a flash memory, a dynamic random access memory (DRAM), a static random access memory (SRAM), and the like to store image data and the like input from the imaging element 112.

The processor 114 is configured of, for example, a central processing unit (CPU), an application processor that executes an operating system, various types of application software, and the like, a graphics processing unit (GPU), a baseband processor, and the like. The processor 114 executes various types of processing on image data input from the imaging element 112, image data read from the storage unit 113, and the like, as necessary. The various types of processing include, for example, processing of displaying an image based on image data, processing of transmitting image data to the outside via a network or the like, and the like.

<Configuration Example of Imaging Element>

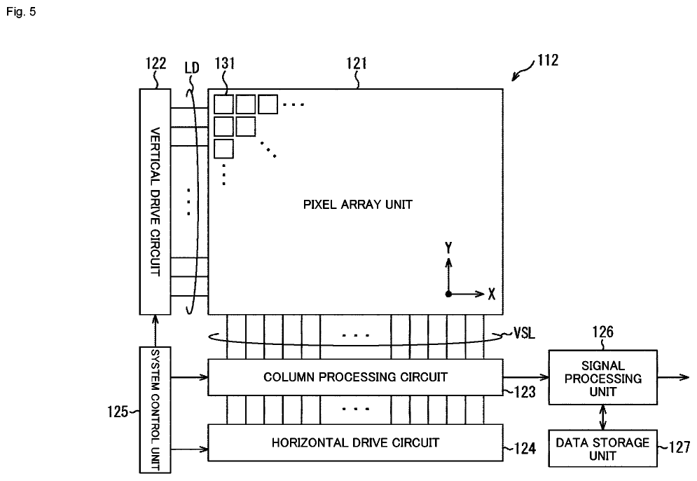

FIG. 5 is a block diagram illustrating a schematic configuration example of the imaging element 112 of FIG. 4.

In this example, the imaging element 112 is configured of a complementary metal oxide semiconductor (CMOS) image sensor. The CMOS image sensor is an image sensor manufactured by applying or partially using a CMOS process.

The imaging element 112 includes a pixel array unit 121, a vertical drive circuit 122, a column processing circuit 123, a horizontal drive circuit 124, a system control unit 125, a signal processing unit 126, and a data storage unit 127. In the following description, the vertical drive circuit 122, the column processing circuit 123, the horizontal drive circuit 124, the system control unit 125, the signal processing unit 126, and the data storage unit 127 are each referred to as a peripheral circuit.

In the pixel array unit 121, unit pixels (hereinafter simply referred to as pixels) 131 each having a photoelectric conversion element such as a photodiode that generates and accumulates an electric charge according to the amount of received light are arranged in a two-dimensional lattice in the row direction and the column direction (hereinafter referred to as a matrix). The row direction refers to the arrangement direction of the pixels 131 in the pixel row (horizontal direction in the drawing), and the column direction refers to the arrangement direction of the pixels 131 in the pixel column (vertical direction in the drawing). Details of a specific circuit configuration of the unit pixel 131 will be described later.

In the pixel array unit 121, with respect to the matrix pixel array, a pixel drive line LD is wired along the row direction for each pixel row, and a vertical signal line VSL is wired along the column direction for each pixel column. The pixel drive line LD transmits a drive signal for performing driving at the time of reading out a signal from the corresponding pixel 131. In this example, the pixel drive line LD is illustrated as one wire, but is not limited to one. One end of the pixel drive line LD is connected to an output end corresponding to each row of the vertical drive circuit 122.

The vertical drive circuit 122, which is configured of a shift register, an address decoder, or the like, drives all of the pixels 131 of the pixel array unit 121 at the same time, in units of rows, or the like. In other words, the vertical drive circuit 122 forms a driving unit that controls operations of the pixels 131 of the pixel array unit 121, together with the system control unit 125 that controls the vertical drive circuit 122. Although a specific configuration of the vertical drive circuit 122 is not illustrated in the drawing, the vertical drive circuit generally includes two scanning systems, that is, a read-out scanning system and a sweep-out scanning system.

The read-out scanning system selectively scans the unit pixels 131 of the pixel array unit 121 in order in units of rows in order to read signals from the unit pixels 131. The signals read from the unit pixels 131 are analog signals. The sweep-out scanning system performs sweep-out scanning on a read-out row on which read-out scanning is performed by the read-out scanning system, ahead of the read-out scanning by an exposure time.

The sweep-out scanning by the sweep-out scanning system sweeps out unnecessary charges from the photodiodes of the unit pixels 131 in the read-out row, thereby resetting the photodiodes. A so-called electronic shutter operation is performed by sweeping out (resetting) the unnecessary charges in the sweeping scanning system. The electronic shutter operation is an operation of discarding the charge of the photodiode and newly starting exposure (starting charge accumulation).

The signal read out by the read-out operation by the read-out scanning system corresponds to the amount of light received after the immediately preceding read-out operation or the electronic shutter operation. A period from a read-out timing of the immediately preceding read-out operation or a sweep-out timing of the electronic shutter operation to a read-out timing of the current read-out operation is a charge storage period (also referred to as an exposure period) in the unit pixel 131.

Signals output from the unit pixels 131 of a pixel row selectively scanned by the vertical drive circuit 122 are input to the column processing circuit 123 through the vertical signal lines VSL for the respective pixel columns. The column processing circuit 123 performs predetermined signal processing on signals output through the vertical signal lines VSL from the pixels 131 of the selected row for the respective pixel columns of the pixel array unit 121 and temporarily holds the pixel signals having been subjected to the signal processing.

Specifically, the column processing circuit 123 performs as signal processing at least noise removal processing such as correlated double sampling (CDS) processing or double data sampling (DDS) processing. For example, the CDS processing removes fixed pattern noise unique to the pixels 131 such as reset noise and variations in threshold values of amplification transistors in the pixels 131. The column processing circuit 123 also has, for example, an analog-digital (AD) conversion function, which converts analog pixel signals read from the photodiodes into digital signals and outputs the digital signals.

The horizontal drive circuit 124, which is configured of a shift register, an address decoder, or the like, selects read-out circuits (hereinafter also referred to as pixel circuits) corresponding to a pixel column of the column processing circuit 123 in order. Pixel signals having been subjected to signal processing for each pixel circuit in the column processing circuit 123 are output in order by selective scanning performed by the horizontal drive circuit 124.

The system control unit 125 is configured of a timing generator that generates various timing signals, or the like, and performs driving control of the vertical drive circuit 122, the column processing circuit 123, the horizontal drive circuit 124, and the like on the basis of various timings generated by the timing generator.

The signal processing unit 126 has at least a calculation processing function and performs various signal processing such as calculation processing on a pixel signal output from the column processing circuit 123.

The data storage unit 127 temporarily stores data required for signal processing performed by the signal processing unit 126 when performing the signal processing.

Image data output from the signal processing unit 126 is subjected to predetermined processing in, for example, the processor 114 or the like in the electronic device 101 including the imaging element 112, or is transmitted to the outside through a network.

<Configuration Example of Unit Pixel>

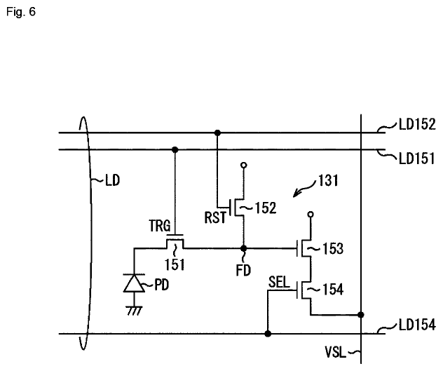

FIG. 6 is a circuit diagram illustrating a schematic configuration example of the unit pixel 131 of FIG. 5. The unit pixel 131 includes a photodiode PD, a transfer transistor 151, a reset transistor 152, an amplification transistor 153, a select transistor 154, and a floating diffusion layer FD.

The anode of the photodiode PD is grounded and the cathode thereof is connected to the source of the transfer transistor 151. The drain of the transfer transistor 151 is connected to the source of the reset transistor 152 and the gate of the amplification transistor 153, and a node that is a connection point thereof forms the floating diffusion layer FD. The drain of the reset transistor 152 is connected to a vertical reset input line that is not illustrated.

The source of the amplification transistor 153 is connected to a vertical current supply line not illustrated. The drain of the amplification transistor 153 is connected to the source of the select transistor 154, and the drain of the select transistor 154 is connected to a vertical signal line VSL.

The gate of the select transistor 154 is connected to a select transistor drive line LD154 included in the pixel drive lines LD. The gate of the reset transistor 152 is connected to a reset transistor drive line LD152 included in the pixel drive lines LD. The gate of the transfer transistor 151 is connected to a transfer transistor drive line LD151 included in the pixel drive lines LD. The drain of the amplification transistor 153 is connected to the vertical signal line VSL, one end of which is connected to the column processing circuit 123, through the select transistor 154.

In the following description, the reset transistor 152, the amplification transistor 153, and the select transistor 154 are also collectively referred to as a pixel circuit. This pixel circuit may include the floating diffusion layer FD and/or the transfer transistor 151. Next, basic functions of the unit pixel 131 will be described.

The reset transistor 152 controls discharge (reset) of the charge accumulated in the floating diffusion layer FD according to a reset signal RST supplied from the vertical drive circuit 122 through the reset transistor drive line LD152. It is also possible to discharge (reset) the charge accumulated in the photodiode PD in addition to the charge accumulated in the floating diffusion layer FD by switching the transfer transistor 151 to an on state when the reset transistor 152 is in an on state.

When a reset signal RST at a high level is input to the gate of the reset transistor 152, the floating diffusion layer FD is clamped to a voltage applied through the vertical reset input line. As a result, the charge accumulated in the floating diffusion layer FD is discharged (reset).

When a reset signal RST at a low level is input to the gate of the reset transistor 152, the floating diffusion layer FD is electrically cut off from the vertical reset input line and enters a floating state.

The photodiode PD performs photoelectric conversion of incident light and generates a charge corresponding to the amount of light. The generated charge is accumulated on the side of the cathode of the photodiode PD.

The transfer transistor 151 controls transfer of the charge from the photodiode PD to the floating diffusion layer FD according to a transfer control signal TRG supplied from the vertical drive circuit 122 through the transfer transistor drive line LD151.

For example, when a transfer control signal TRG at a high level is input to the gate of the transfer transistor 151, the charge accumulated in the photodiode PD is transferred to the floating diffusion layer FD. On the other hand, when a transfer control signal TRG at a low level is supplied to the gate of the transfer transistor 151, the transfer of the charge from the photodiode PD stops.

The floating diffusion layer FD has a function of converting the charge transferred from the photodiode PD through the transfer transistor 151 into a voltage having a voltage value corresponding to the amount of charge. Accordingly, in a floating state in which the reset transistor 152 is turned off, the electric potential of the floating diffusion layer FD is modulated in response to the amount of charge accumulated therein.

The amplification transistor 153 serves as an amplifier having a variation in the electric potential of the floating diffusion layer FD connected to the gate thereof as an input signal, and an output voltage signal of the amplification transistor 153 appears as a pixel signal on the vertical signal line VSL through the select transistor 154.

The select transistor 154 controls appearance of a pixel signal on the vertical signal line VSL according to the amplification transistor 153 in response to the select control signal SEL supplied from the vertical drive circuit 122 through the select transistor drive line LD154. For example, when a select control signal SEL at a high level is input to the gate of the select transistor 154, a pixel signal according to the amplification transistor 153 appears on the vertical signal line VSL. On the other hand, when a select control signal SEL at a low level is input to the gate of the select transistor 154, the appearance of the pixel signal on the vertical signal line VSL stops. Accordingly, in the vertical signal line VSL to which a plurality of unit pixels 131 are connected, only the output of a selected unit pixel 131 can be extracted.

<Configuration Example of Semiconductor Package>

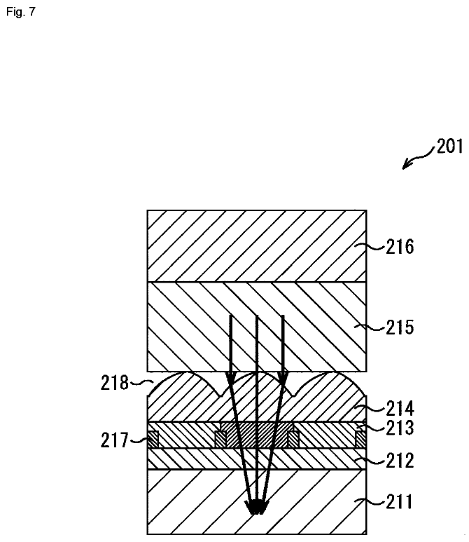

FIG. 7 is a cross-sectional view schematically illustrating a configuration example of a semiconductor package 201 including the imaging element 112 of FIG. 5.

In the semiconductor package 201, a plurality of layers are stacked in the order of a semiconductor substrate 211, an insulating film 212, color filters 213, on-chip lenses 214, a resin layer 215, and a glass substrate 216 from the bottom in the drawing.

The semiconductor substrate 211 is, for example, a substrate made of silicon or the like, and the unit pixels 131 (not illustrated) of FIG. 6 are arranged in a matrix. The photodiodes PD (not illustrated) of the respective unit pixels 131 are arranged in a matrix in the vicinity of the back surface (upper surface in the drawing) of the semiconductor substrate 211, and incident light enters the photodiodes PD from the back surface side. In other words, the imaging element 112 included in the semiconductor package 201 is a backside-illumination type CMOS image sensor.

The upper surface of each layer of the semiconductor package 201 in the drawing, that is, the surface where incident light enters is hereinafter referred to as the incident surface.

The insulating film 212 is formed on the incident surface of the semiconductor substrate 211.

The color filters 213 are stacked on the insulating film 212. The color filters 213 includes filters of colors corresponding to the respective unit pixels 131 formed on the semiconductor substrate 211. In addition, the color filters 213 are provided with a light shielding film 217 for shielding each pixel from light from adjacent pixels.

Each on-chip lens 214 is made of, for example, SiN or SiO, and has a refractive index set within a range of, for example, 1.4 to 2.0. The on-chip lenses 214 are arranged in a matrix on the color filters 213 for the respective unit pixels 131 formed on the semiconductor substrate 211. Each on-chip lens 214 collects incident light onto the light receiving surface of the photodiode PD of the corresponding unit pixel 131.

The resin layer 215 is made of, for example, a transparent resin such as epoxy resin, low-melting glass, or ultraviolet curable resin, and has a refractive index set to a value greater than that of air, for example, about 1.4. The resin layer 215 serves to bond the glass substrate 216 to the semiconductor substrate 211 on which the on-chip lenses 214 and others are formed.

The resin layer 215 is in contact with a portion including the most protruding portion of each on-chip lens 214 (hereinafter referred to as the central portion). On the other hand, a space (hereinafter referred to as an air gap) 218 is provided between a peripheral portion around the central portion of the on-chip lens 214 and the resin layer 215. The maximum height of the air gap 218, that is, the distance between the bottom surface of the resin layer 215 and the most recessed portion (lowest portion) of the on-chip lens 214 is set to, for example, 100 nm or more.

The glass substrate 216 is bonded via the resin layer 215 to the semiconductor substrate 211 on which the insulating film 212 to the on-chip lens 214 are formed. In other words, the glass substrate 216 is in contact with the incident surface of the resin layer 215 (the surface opposite to the surface in contact with the on-chip lens 214). The glass substrate 216 serves to protect the incident surface of the semiconductor substrate 211 and also maintain the physical strength of the semiconductor package 201.

The refractive index of the glass substrate 216 is set within a range of 1.4 to 1.5, for example.

In the semiconductor package 201, incident light, which enters the glass substrate 216, passes through the glass substrate 216 and the resin layer 215, and then enters the on-chip lens 214. The incident light entering the on-chip lens 214 is collected by the on-chip lens 214 onto the light receiving surface of the photodiode PD formed on the semiconductor substrate 211.

Incident light entering the central portion of the on-chip lens 214 directly enters the on-chip lens 214 from the resin layer 215.

On the other hand, incident light entering the peripheral portion of the on-chip lens 214 once enters the air gap 218 from the resin layer 215 and then enters the on-chip lens 214 via the air gap 218. At this time, since the refractive index of the resin layer 215 (approximately 1.4) is greater than the refractive index of the air in the air gap 218 (approximately 1.0), the exit angle of the incident light from the interface between the resin layer 215 and the air gap 218 is larger than the incident angle to that interface.

Therefore, the incident angle of the incident light on the peripheral portion of the on-chip lens 214 is larger than in the case where no air gap is provided between the resin layer 41 and the on-chip lens 71 as in the semiconductor package 61 of FIG. 3. As a result, the focal length of each on-chip lens 214 can be shortened without increasing the curvature of the on-chip lens 214.

As described above, the height of the semiconductor package 201 can be reduced as with the semiconductor package 61 in FIG. 3 without increasing the curvature of each on-chip lens 214. Further, as compared to the on-chip lenses 71 of the semiconductor package 61 of FIG. 3, the on-chip lenses 214 are easier to manufacture, and for example, the on-chip lenses 214 can be manufactured using conventional processes.

In addition, since the air gap 218 is provided between the peripheral portion of each on-chip lens 214 and the resin layer 215 where no resin is embedded, the occurrence of cracks is prevented and the quality of the semiconductor package 201 is improved.

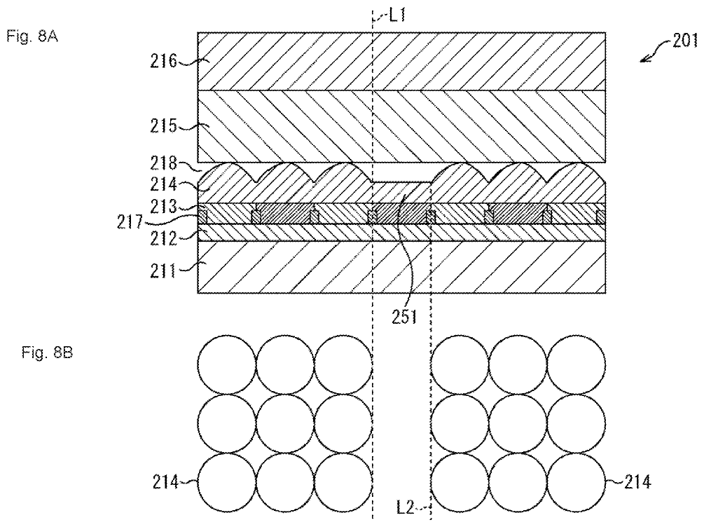

Next, with reference to FIGS. 8 to 10, configuration examples of a peripheral region around a pixel region in which unit pixels 131 of the semiconductor package 201 are arranged will be described.

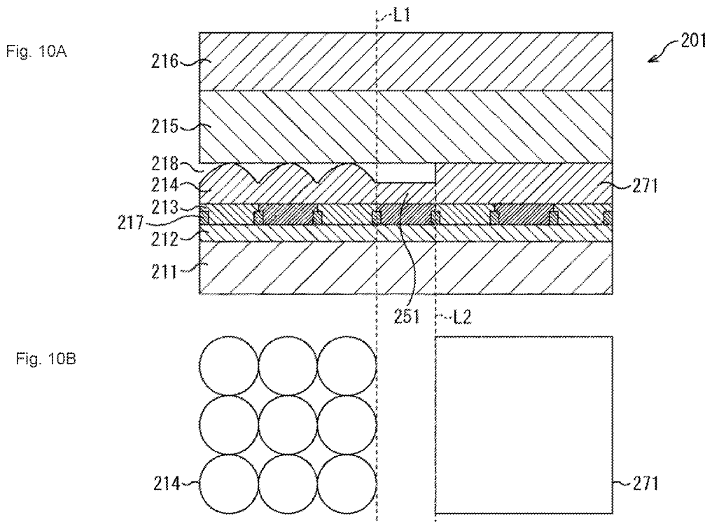

A of FIG. 8 to A of FIG. 10 are schematic cross-sectional views of the vicinity of a boundary between the pixel region and the peripheral region of the semiconductor package 201. B of FIG. 8 to B of FIG. 10 are schematic plan views of a layer (hereinafter referred to as an on-chip lens layer) in which on-chip lenses 214 are arranged in the vicinity of the boundary between the pixel region and the peripheral region of the semiconductor package 201. In FIGS. 8 to 10, the left side of a boundary line L1 is the pixel region, and the right side is the peripheral region.

In the example of FIG. 8, the pixel region and the peripheral region have substantially the same layer structure. Specifically, a region outside an auxiliary line L2 in the peripheral region has the same layer structure as the pixel region. On the other hand, in a region in the peripheral region adjacent to the pixel region (a region between the boundary line L1 and the auxiliary line L2), there is no on-chip lens 214 in the on-chip lens layer, and a flat region 251 is formed with the same height as that of the lower end of the on-chip lenses 214.

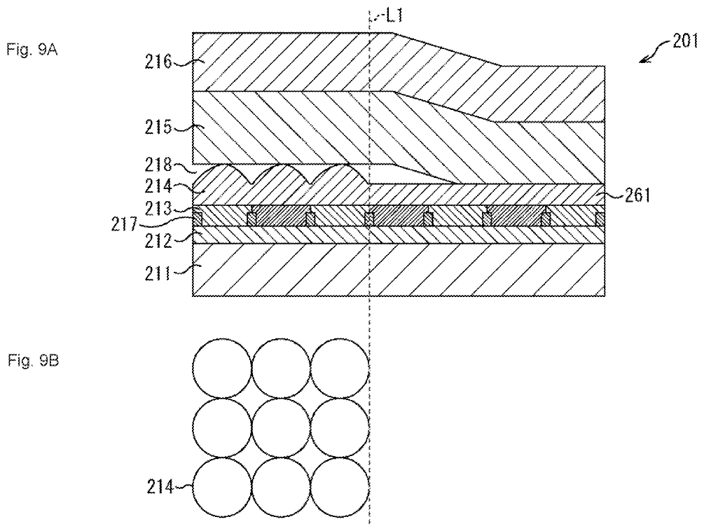

In the example of FIG. 9, there is no on-chip lens 214 in the peripheral region. Specifically, in the peripheral region, there is no on-chip lens 214 in the on-chip lens layer, and a flat region 261 is formed with the same height as that of the lower end of the on-chip lenses 214. The resin layer 215 and the glass substrate 216 are inclined downward in the vicinity of the boundary between the peripheral region and the pixel region, and the top of the peripheral region is lower than the top of the pixel region.

The example in FIG. 10 differs from the example in FIG. 8 in that a flat region 271 is formed instead of the on-chip lenses 214 in the peripheral region. The flat region 271 has the same height as the upper end of the on-chip lenses 214, and the flat region 271 keeps the resin layer 215 and the glass substrate 216 at the same height as the pixel region in the peripheral region.

<Process of Manufacturing Semiconductor Package>

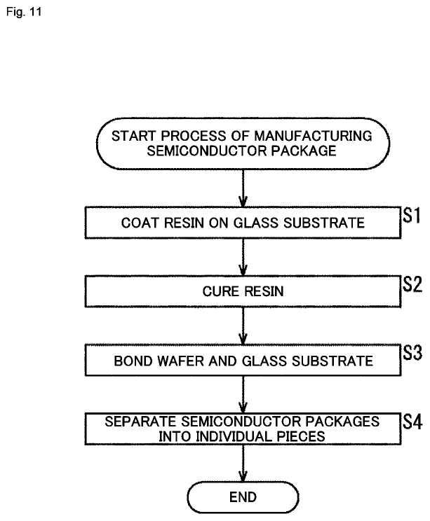

Next, an example of part of a process of manufacturing the semiconductor package 201 of FIG. 7 will be described with reference to the flowchart of FIG. 11.

In the following, it is assumed that layers corresponding to the semiconductor substrates 211 to the on-chip lenses 214 of the plurality of semiconductor packages 201 have already been formed on a wafer.

In step S1, a resin is coated on a glass substrate. Specifically, a glass substrate having the same shape in the plane direction as the wafer is used for the glass substrate 216 of the semiconductor package 201, and a resin used for the resin layer 215 is coated on one side of the glass substrate. Hereinafter, the surface of the glass substrate on which the resin is coated is referred to as the bonding surface.

In step S2, the resin is cured. Specifically, the glass substrate coated with the resin is subjected to processing necessary for curing the resin, such as heating or UV curing (ultraviolet curing). As a result, the resin coated on the glass substrate is cured.

In this step, it is desirable to cure the resin as hard as possible while maintaining the adhesive force of the resin. This makes it possible to stably bond the wafer and the glass substrate together in the processing of step S3.

In step S3, the wafer and the glass substrate are bonded together. Specifically, the wafer and the glass substrate are bonded together after the surface of the wafer on which the on-chip lenses 214 are formed and the bonding surface of the glass substrate faces each other so that they are aligned. As a method for the bonding, for example, a technique using surface energy between substrates is desirably used such as plasma bonding or normal temperature bonding.

In step S4, the semiconductor packages 201 are separated into individual pieces. Specifically, the wafer to which the glass substrate is bonded is diced, and the plurality of semiconductor packages 201 formed on the wafer are separated into individual pieces.

After that, the process of manufacturing the semiconductor package ends.

In this way, a resin is coated on the glass substrate side instead of the wafer on which the on-chip lenses 214 are formed, and then the wafer and the glass substrate are bonded together, so that the air gap 218 of the semiconductor package 201 can be easily and stably formed.

### 3. Modification Examples

Hereinafter, modification examples of the above-described embodiments of the present technology will be described.

For example, in the semiconductor package 201, a planarization layer may be provided between the insulating film 12 and the color filters 14, as in the semiconductor package 31 of FIG. 2. In this case, as described above, since the focal length of each on-chip lens 214 can be shortened, the thickness of the planarization layer can be reduced.

For example, a semiconductor substrate including peripheral circuits and the like may be stacked under the semiconductor substrate 211.

For example, the refractive index of the resin layer 215 can be set within a range of 1.0 to 1.5.

However, if the refractive index of the resin layer 215 is set to around 1.0, the refractive index of the resin layer 215 and the refractive index of the air in the air gap 218 become almost the same, so that the incident light is hardly refracted at the interface between the resin layer 215 and the air gap 218. Therefore, it is necessary to set the curvature of each on-chip lens 214 to be substantially the same as the curvature of each on-chip lens 71 of the semiconductor package 61 of FIG. 3. Note that, even if the curvature of each on-chip lens 214 is set to be substantially the same as the curvature of each on-chip lens 71, the occurrence of cracks in the resin layer 215 can be prevented because of the air gap 218 provided.

The present technology can be applied not only to the above-described backside-illumination type imaging element, but also to a frontside-illumination type image sensor. In this case, for example, a wiring layer is provided between the color filters and the semiconductor substrate (insulating film).

### 4. Application Example

<Application Example of Present Technology>

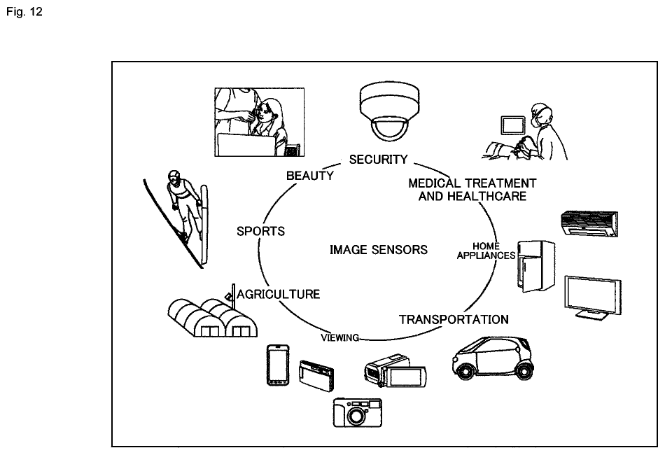

For example, as illustrated in FIG. 12, the present technology can be applied to various cases in which light such as visible light, infrared light, ultraviolet light, or X-ray is sensed.
Devices that capture images used for viewing, such as digital cameras and mobile devices with camera functions
Devices used for transportation, such as in-vehicle sensors that capture front, rear, surrounding, and interior view images of automobiles, monitoring cameras that monitor traveling vehicles and roads, ranging sensors that measure a distance between vehicles, and the like, for safe driving such as automatic stop, recognition of a driver's condition, and the like
Devices used for home appliances such as TVs, refrigerators, and air conditioners in order to capture an image of a user's gesture and perform device operations in accordance with the gesture
Devices used for medical treatment and healthcare, such as endoscopes and devices that perform angiography by receiving infrared light
Devices used for security, such as monitoring cameras for crime prevention and cameras for personal authentication
Devices used for beauty, such as a skin measuring device that captures images of the skin and a microscope that captures images of the scalp
Devices used for sports, such as action cameras and wearable cameras for sports applications
Devices used for agriculture, such as cameras for monitoring conditions of fields and crops

A more specific application example will be described below.

<Application Example to Endoscopic Surgery System>

For example, the technology according to the present disclosure may be applied to an endoscopic surgery system.

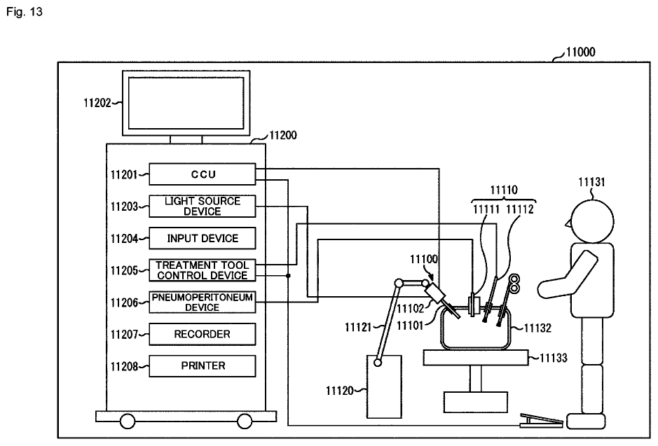

FIG. 13 is a diagram illustrating an example of a schematic configuration of an endoscope surgery system to which the technology according to the present disclosure (the present technology) is applied.

FIG. 13 illustrates a state where a surgeon (doctor) 11131 is performing a surgical operation on a patient 11132 on a patient bed 11133 by using the endoscopic surgery system 11000. As illustrated, the endoscopic surgery system 11000 includes an endoscope 11100, other surgical instruments 11110 such as a pneumoperitoneum tube 11111 and an energy treatment tool 11112, a support arm device 11120 that supports the endoscope 11100, and a cart 11200 equipped with various devices for endoscopic surgery.

The endoscope 11100 includes a lens barrel 11101 of which a region having a predetermined length from a tip thereof is inserted into a body cavity of the patient 11132, and a camera head 11102 connected to a base end of the lens barrel 11101. In the illustrated example, the endoscope 11100 configured as a so-called rigid endoscope having the rigid lens barrel 11101 is illustrated, but the endoscope 11100 may be configured as a so-called flexible endoscope having a flexible lens barrel.

The distal end of the lens barrel 11101 is provided with an opening into which an objective lens is fitted. A light source device 11203 is connected to the endoscope 11100, light generated by the light source device 11203 is guided to the distal end of the lens barrel 11101 by a light guide extended to the inside of the lens barrel 11101, and the light is radiated toward an observation target in the body cavity of the patient 11132 through the objective lens. The endoscope 11100 may be a direct-viewing endoscope, an oblique-viewing endoscope, or a side-viewing endoscope.

An optical system and an imaging element are provided inside the camera head 11102, and reflected light (observation light) from the observation target is condensed onto the imaging element by the optical system. The imaging element photoelectrically converts the observation light to generate an electric signal corresponding to the observation light, that is, an image signal corresponding to an observation image. The image signal is transmitted to a camera control unit (CCU) 11201 as RAW data.

The CCU 11201 includes a central processing unit (CPU), a graphics processing unit (GPU), or the like, and comprehensively controls the operations of the endoscope 11100 and a display device 11202. The CCU 11201 receives an image signal from the camera head 11102 and performs various types of image processing such as development processing (demosaicing) on the image signal to display an image based on the image signal.

The display device 11202 displays the image based on the image signal subjected to the image processing by the CCU 11201 under the control of the CCU 11201.

The light source device 11203 includes a light source such as a light emitting diode (LED) and supplies the endoscope 11100 with irradiation light for imaging a surgical site or the like.

An input device 11204 is an input interface for the endoscopic surgery system 11000. The user can input various types of information and instructions to the endoscopic surgery system 11000 via the input device 11204. For example, the user inputs an instruction or the like to change the imaging conditions (type of irradiation light, magnification, focal length, and the like) for the endoscope 11100.

A treatment tool control device 11205 controls driving of the energy treatment tool 11112 for cauterization or incision of a tissue, sealing of blood vessel, or the like. A pneumoperitoneum device 11206 sends a gas into the body cavity of the patient 11132 via the pneumoperitoneum tube 11111 in order to inflate the body cavity for the purpose of securing a field of view using the endoscope 11100 and a working space of the surgeon. A recorder 11207 is a device capable of recording various types of information on surgery. A printer 11208 is a device capable of printing various types of information on surgery in various formats such as text, images, and graphs.

The light source device 11203, which supplies irradiation light to the endoscope 11100 to capture an image of a surgical site, can include, for example, an LED, a laser light source, or a white light source composed of a combination thereof. In a case where a white light source to be used is composed of a combination of RGB laser light sources, the intensity and timing of output of each color (each wavelength) can be controlled with high accuracy, and thus it is possible to adjust white balance of a captured image in the light source device 11203. In this case, by time-divisionally irradiating an observation target with laser light from the RGB laser light source and controlling driving of the imaging element of the camera head 11102 in synchronization with the irradiation timing, it is also possible to time-divisionally capture images corresponding to RGB. According to this method, it is possible to obtain a color image without providing a color filter in the image sensor.

Further, driving of the light source device 11203 may be controlled so that an intensity of output light is changed at predetermined time intervals. The driving of the image sensor of the camera head 11102 is controlled in synchronization with a timing of changing the intensity of the light, and images are acquired in a time division manner and combined, such that an image having a high dynamic range without so-called blackout and whiteout can be generated.

The light source device 11203 may be configured to be able to supply light in a predetermined wavelength band corresponding to special light observation. In the special light observation, for example, so-called narrow band imaging is performed in which images of a predetermined tissue such as a blood vessel of the mucosal surface layer are captured with high contrast by irradiating the tissue with a narrower band of light than the irradiation light (that is, white light) used for normal observation by using the wavelength dependence of light absorption in body tissues. Alternatively, in the special light observation, fluorescence observation may be performed in which an image is obtained from fluorescence generated by irradiation with excitation light. In the fluorescence observation, a body tissue can be irradiated with excitation light to observe the fluorescence from the body tissue (autofluorescence observation), or a reagent such as indocyanine green (ICG) can be locally injected into a body tissue and then the body tissue can be irradiated with excitation light corresponding to the fluorescence wavelength of the reagent to obtain a fluorescence image. The light source device 11203 can be configured to be able to supply narrow band light and/or excitation light corresponding to such special light observation.

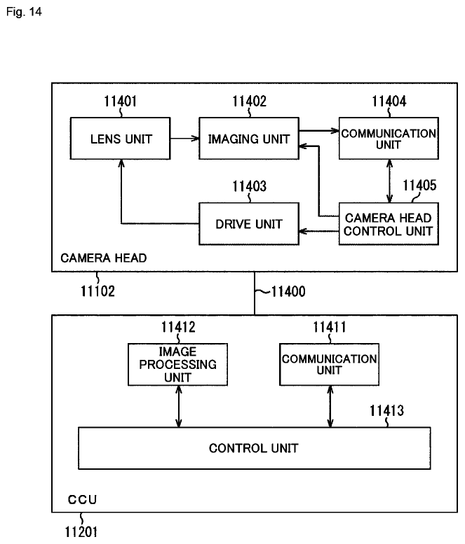

FIG. 14 is a block diagram illustrating an example of functional configurations of the camera head 11102 and the CCU 11201 illustrated in FIG. 13.

The camera head 11102 includes a lens unit 11401, an imaging unit 11402, a drive unit 11403, a communication unit 11404, and a camera head control unit 11405. The CCU 11201 has a communication unit 11411, an image processing unit 11412, and a control unit 11413. The camera head 11102 and the CCU 11201 are communicatively connected to each other by a transmission cable 11400.

The lens unit 11401 is an optical system provided in a connection portion for connection to the lens barrel 11101. Observation light taken from a tip of the lens barrel 11101 is guided to the camera head 11102 and is incident on the lens unit 11401. The lens unit 11401 is configured in combination of a plurality of lenses including a zoom lens and a focus lens.

The imaging unit 11402 may be configured of a single imaging element constituting (so-called single-plate type) or a plurality of imaging elements (so-called multi-plate type). In the case where the imaging unit 11402 is configured as being of a multi-plate type, for example, image signals corresponding to RGB may be generated by the imaging elements and synthesized to obtain a color image. Alternatively, the imaging unit 11402 may be configured to have a pair of imaging elements to acquire right-eye and left-eye image signals for 3D (dimensional) display. The performed 3D display allows the surgeon 11131 to more accurately ascertain a depth of a living tissue in the surgical site. In the case where the imaging unit 11402 is configured as being of a multi-plate type, a plurality of systems of lens units 11401 may be provided corresponding to the imaging elements.

The imaging unit 11402 need not necessarily be provided in the camera head 11102. For example, the imaging unit 11402 may be provided immediately after the objective lens inside the lens barrel 11101.

The drive unit 11403 is configured by an actuator and the zoom lens and the focus lens of the lens unit 11401 are moved by a predetermined distance along an optical axis under the control of the camera head control unit 11405. Accordingly, the magnification and focus of the image captured by the imaging unit 11402 can be adjusted appropriately.

The communication unit 11404 is configured using a communication device for transmitting and receiving various types of information to and from the CCU 11201. The communication unit 11404 transmits the image signal obtained from the imaging unit 11402 as RAW data to the CCU 11201 via the transmission cable 11400.

The communication unit 11404 receives a control signal for controlling driving of the camera head 11102 from the CCU 11201 and supplies the camera head control unit 11405 with the control signal. The control signal includes, for example, information regarding imaging conditions such as information indicating designation of a frame rate of a captured image, information indicating designation of an exposure value at the time of imaging, and/or information indicating designation of a magnification and a focus of the captured image.

The above-mentioned imaging conditions such as the frame rate, exposure value, magnification, and focus may be appropriately designated by the user, or may be automatically set by the control unit 11413 of the CCU 11201 based on the acquired image signal. In the latter case, the endoscope 11100 is to be equipped with a so-called auto exposure (AE) function, auto focus (AF) function, and auto white balance (AWB) function.

The camera head control unit 11405 controls driving of the camera head 11102 based on a control signal from the CCU 11201 received via the communication unit 11404.

The communication unit 11411 is configured of a communication device that transmits and receives various types of information to and from the camera head 11102. The communication unit 11411 receives an image signal transmitted via the transmission cable 11400 from the camera head 11102.

The communication unit 11411 transmits the control signal for controlling the driving of the camera head 11102 to the camera head 11102. The image signal or the control signal can be transmitted through electric communication, optical communication, or the like.

The image processing unit 11412 performs various types of image processing on the image signal that is the RAW data transmitted from the camera head 11102.

The control unit 11413 performs various types of control on imaging of a surgical site by the endoscope 11100, display of a captured image obtained through imaging of a surgical site, or the like. For example, the control unit 11413 generates a control signal for controlling driving of the camera head 11102.

The control unit 11413 causes the display device 11202 to display a captured image in which a surgical site or the like appears based on an image signal subjected to the image processing by the image processing unit 11412. In this case, the control unit 11413 may recognize various objects in the captured image using various image recognition techniques. For example, the control unit 11413 can recognize a surgical instrument such as forceps, a specific biological site, bleeding, mist or the like at the time of use of the energy treatment tool 11112, or the like by detecting a shape, a color, or the like of an edge of an object included in the captured image. When the display device 11202 is caused to display a captured image, the control unit 11413 may superimpose various types of surgery support information on an image of the surgical site for display using a recognition result of the captured image. By displaying the surgery support information in a superimposed manner and presenting it to the surgeon 11131, a burden on the surgeon 11131 can be reduced, and the surgeon 11131 can reliably proceed with the surgery.

The transmission cable 11400 that connects the camera head 11102 and the CCU 11201 is an electrical signal cable compatible with communication of electrical signals, an optical fiber compatible with optical communication, or a composite cable of these.

Here, although wired communication is performed using the transmission cable 11400 in the illustrated example, communication between the camera head 11102 and the CCU 11201 may be performed wirelessly.

An example of the endoscopic surgery system to which the technology according to the present disclosure can be applied has been described above. The technology according to the present disclosure can be applied to, for example, the imaging unit 11402 of the camera head 11102, or the like in the configurations described above. Specifically, the semiconductor package 201 of FIG. 7 can be applied to, for example, the imaging unit 11402. By applying the technology according to the present disclosure to the imaging unit 11402, it is possible to reduce the size of the imaging unit 11402 and thus to reduce the size of the camera head 11102.

Here, although the endoscopic operation system has been described as an example, the technology according to the present disclosure may be applied to other, for example, a microscopic operation system.

<Application Example to Mobile Object>

For example, the technology according to the present disclosure may be realized as a device equipped in any type of mobile object such as an automobile, an electric vehicle, a hybrid electric vehicle, a motorcycle, a bicycle, a personal mobility device, an airplane, a drone, a ship, and a robot.

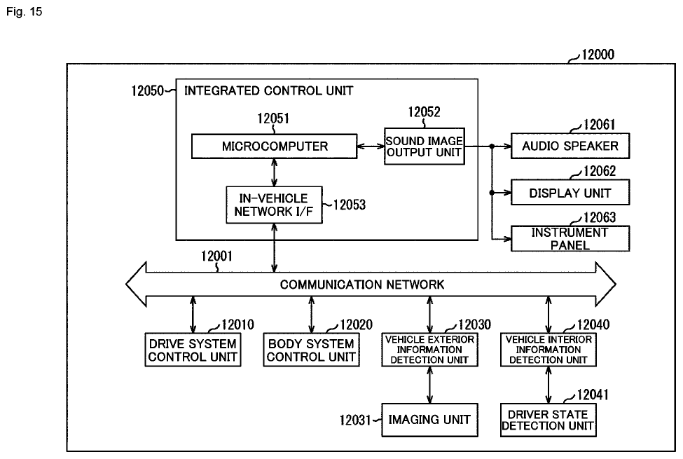

FIG. 15 is a block diagram illustrating a schematic configuration example of a vehicle control system, which is an example of a mobile object control system to which the technology according to the present disclosure can be applied.

The vehicle control system 12000 includes a plurality of electronic control units connected to each other via a communication network 12001. In the example illustrated in FIG. 15, the vehicle control system 12000 includes a drive system control unit 12010, a body system control unit 12020, a vehicle exterior information detection unit 12030, a vehicle interior information detection unit 12040, and an integrated control unit 12050. As a functional configuration of the integrated control unit 12050, a microcomputer 12051, a sound image output unit 12052, and an in-vehicle network I/F (interface) 12053 are illustrated.

The drive system control unit 12010 controls operations of devices related to a drive system of a vehicle according to various programs. For example, the drive system control unit 12010 functions as a control device for: a driving force generation device for generating the driving force of the vehicle such as an internal combustion engine or a drive motor; a driving force transmission mechanism for transmitting the driving force to the wheels; a steering mechanism for adjusting the steering angle of the vehicle; a braking device for generating the braking force of the vehicle; and the like.

The body system control unit 12020 controls operations of various devices mounted in the vehicle body according to various programs. For example, the body system control unit 12020 functions as a control device for: a keyless entry system; a smart key system; a power window device; and various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information on the outside of the vehicle having the vehicle control system 12000 mounted thereon. For example, an imaging unit 12031 is connected to the vehicle exterior information detection unit 12030. The vehicle exterior information detection unit 12030 causes the imaging unit 12031 to capture an image of the outside of the vehicle and receives the captured image. The vehicle exterior information detection unit 12030 may perform object detection processing or distance detection processing for peoples, cars, obstacles, signs, and letters on the road on the basis of the received image.

The imaging unit 12031 is an optical sensor that receives light and outputs an electrical signal according to the amount of the received light. The imaging unit 12031 can also output the electrical signal as an image or distance measurement information. The light received by the imaging unit 12031 may be visible light or invisible light such as infrared light.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing based on detection information input from the driver state detection unit 12041.

The microcomputer 12051 can calculate control target values for the driving force generation device, the steering mechanism, or the braking device based on the information on the inside and outside of the vehicle acquired by the vehicle exterior information detection unit 12030 or the vehicle interior information detection unit 12040, and output control commands to the drive system control unit 12010. For example, the microcomputer 12051 can perform cooperative control for the purpose of implementing functions of an advanced driver assistance system (ADAS) including vehicle collision avoidance, impact mitigation, following traveling based on an inter-vehicle distance, vehicle speed maintenance driving, vehicle collision warning, and vehicle lane deviation warning.

Further, the microcomputer 12051 can perform cooperative control for the purpose of automated driving or the like in which automated driving is performed without depending on operations of the driver, by controlling the driving force generation device, the steering mechanism, or the braking device and the like based on information on the surroundings of the vehicle, the information being acquired by the vehicle exterior information detection unit 12030 or the vehicle interior information detection unit 12040.

The microcomputer 12051 can also output a control command to the body system control unit 12020 based on the information acquired by the vehicle exterior information detection unit 12030 outside the vehicle. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The sound image output unit 12052 transmits an output signal of at least one of sound and an image to an output device capable of visually or audibly notifying a passenger or the outside of the vehicle of information. In the example illustrated in FIG. 15, an audio speaker 12061, a display unit 12062, and an instrument panel 12063 are illustrated as output devices. The display unit 12062 may include at least one of an on-board display and a head-up display, for example.

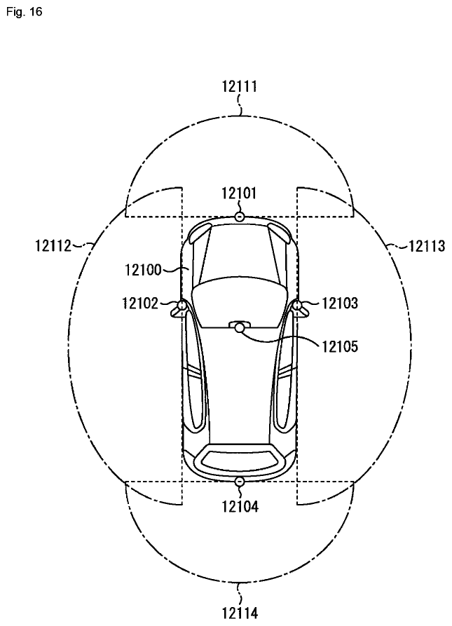

FIG. 16 is a diagram illustrating an example of the installation position of the imaging unit 12031.

In FIG. 16, the imaging unit 12031 includes imaging units 12101, 12102, 12103, 12104, and 12105.

The imaging units 12101, 12102, 12103, 12104, and 12105 are provided at, for example, positions of a front nose, side mirrors, a rear bumper, a back door, an upper portion of a vehicle internal front windshield, and the like of a vehicle 12100. The imaging unit 12101 provided on a front nose and the imaging unit 12105 provided in an upper portion of the vehicle internal front windshield mainly acquire images in front of the vehicle 12100. The imaging units 12102 and 12103 provided in the side mirrors mainly acquire images on the lateral sides of the vehicle 12100. The imaging unit 12104 included in the rear bumper or the back door mainly acquires an image of an area behind the vehicle 12100. The imaging unit 12105 included in the upper portion of the windshield inside the vehicle is mainly used for detection of a preceding vehicle, a pedestrian, an obstacle, a traffic signal, a traffic sign, a lane, or the like.

FIG. 16 illustrates an example of imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, by superimposing image data captured by the imaging units 12101 to 12104, it is possible to obtain a bird's-eye view image viewed from the upper side of the vehicle 12100.

At least one of the imaging units 12101 to 12104 may have a function for obtaining distance information. For example, at least one of the imaging units 12101 to 12104 may be a stereo camera composed of a plurality of imaging elements or may be an imaging element that has pixels for phase difference detection.

For example, the microcomputer 12051 can extract, particularly, a closest three-dimensional object on a path through which the vehicle 12100 is traveling, which is a three-dimensional object traveling at a predetermined speed (for example, 0 km/h or higher) in the substantially same direction as the vehicle 12100, as a preceding vehicle by acquiring a distance to each three-dimensional object in the imaging ranges 12111 to 12114 and temporal change in the distance (a relative speed with respect to the vehicle 12100) on the basis of distance information obtained from the imaging units 12101 to 12104. The microcomputer 12051 can also set an inter-vehicle distance to the preceding vehicle to be secured in advance and perform automatic brake control (including following stop control) and automatic acceleration control (including following start control). Thus, it is possible to perform cooperative control for the purpose of, for example, automated driving in which the vehicle travels in an automated manner without requiring the driver to perform operations.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging units 12101 to 12104 and can use the three-dimensional data to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than a set value and there is a possibility of collision, an alarm is output to the driver through the audio speaker 12061 or the display unit 12062, forced deceleration or avoidance steering is performed through the drive system control unit 12010, and thus it is possible to perform driving support for collision avoidance.

At least one of the imaging units 12101 to 12104 may be an infrared camera that detects infrared rays. For example, the microcomputer 12051 can recognize a pedestrian by determining whether there is a pedestrian in the captured image from the imaging units 12101 to 12104. Such pedestrian recognition is performed by, for example, a procedure in which feature points in the captured images from the imaging units 12101 to 12104 as infrared cameras are extracted and a procedure in which pattern matching processing is performed on a series of feature points indicating an outline of an object to determine whether or not the object is a pedestrian. When the microcomputer 12051 determines that there is a pedestrian in the captured images from the imaging units 12101 to 12104 and the pedestrian is recognized, the sound image output unit 12052 controls the display unit 12062 so that a square contour line for emphasis is superimposed and displayed with the recognized pedestrian. In addition, the sound image output unit 12052 may control the display unit 12062 so that an icon indicating a pedestrian or the like is displayed at a desired position.

An example of the vehicle control system to which the technology according to the present disclosure can be applied has been described above. The technology according to the present disclosure can be applied to, for example, the imaging unit 12301 among the components described above. Specifically, the semiconductor package 201 of FIG. 7 can be applied to, for example, the imaging unit 12301. By applying the technology according to the present disclosure to the imaging unit 12301, it is possible to reduce the size of the imaging unit 12301.

### 5. Others

The embodiments of the present technology are not limited to the aforementioned embodiments, and various changes can be made without departing from the gist of the present technology.

<Combination Example of Configuration>

The present technology can be configured as follows.

(1)

A semiconductor package including:
a semiconductor substrate including a light receiving element;
an on-chip lens disposed on an incident surface side of the semiconductor substrate;
a resin layer in contact with a central portion including a most protruding portion of the on-chip lens; and
a glass substrate in contact with a surface of the resin layer opposite to a surface of the resin layer in contact with the on-chip lens,
wherein
a space is provided between a peripheral portion around the central portion of the on-chip lens and the resin layer.

(2)

The semiconductor package according to (1), wherein the resin layer has a refractive index within a range of 1.0 to 1.5.

(3)

The semiconductor package according to (2), wherein the refractive index of the resin layer is greater than a refractive index of air

(4)

The semiconductor package according to any one of (1) to (3), wherein the resin layer is made of epoxy resin, low-melting glass, or ultraviolet curable resin.

(5)

The semiconductor package according to any one of (1) to (4), wherein a maximum height of the space is 100 nm or more.

(6)

The semiconductor package according to any one of (1) to (5), wherein a color filter is disposed between the semiconductor substrate and the on-chip lens.

(7)

The semiconductor package according to (6), wherein a planarization layer is disposed between the semiconductor substrate and the color filter.

(8)

The semiconductor package according to (6), wherein a wiring layer is disposed between the semiconductor substrate and the color filter.

(9)

The semiconductor package according to any one of (1) to (8), wherein a flat region having the same height as an upper end of the on-chip lens is formed in a peripheral region around a pixel region in which pixels are arranged.

(10)

A method for manufacturing a semiconductor package, including:
a coating step of coating a resin on one surface of a glass substrate;
a curing step of curing the resin; and
a bonding step of bonding a surface of a wafer on which an on-chip lens is formed and the surface of the glass substrate on which the resin is coated.

(11)

The method for manufacturing a semiconductor package according to (10), wherein the bonding step includes bonding the wafer and the glass substrate by using surface energy therebetween.

(12)

The method for manufacturing a semiconductor package according to (10) or (11), further including a separating step of separating the wafer to which the glass substrate is bonded into individual semiconductor packages.

The advantageous effects described in the present specification are merely exemplary and are not limited, and other advantageous effects may be obtained.

### REFERENCE SIGNS LIST

101 Electronic device

112 Imaging element

121 Pixel array unit

131 Unit pixel

201 Semiconductor package

211 Semiconductor substrate

212 Insulating film

213 Color filter

214 On-chip lens

215 Resin layer

216 Semiconductor substrate

218 Space (air gap)

251 to 271 Flat region

1. A semiconductor package comprising:
a semiconductor substrate including a light receiving element;
an on-chip lens disposed on an incident surface side of the semiconductor substrate;
a resin layer in contact with a central portion including a most protruding portion of the on-chip lens; and
a glass substrate in contact with a surface of the resin layer opposite to a surface of the resin layer in contact with the on-chip lens,
wherein
a space is provided between a peripheral portion around the central portion of the on-chip lens and the resin layer.

2. The semiconductor package according to claim 1, wherein the resin layer has a refractive index within a range of 1.0 to 1.5.

3. The semiconductor package according to claim 2, wherein the refractive index of the resin layer is greater than a refractive index of air.

4. The semiconductor package according to claim 1, wherein the resin layer is made of epoxy resin, low-melting glass, or ultraviolet curable resin.

5. The semiconductor package according to claim 1, wherein a maximum height of the space is 100 nm or more.

6. The semiconductor package according to claim 1, wherein a color filter is disposed between the semiconductor substrate and the on-chip lens.

7. The semiconductor package according to claim 6, wherein a planarization layer is disposed between the semiconductor substrate and the color filter.

8. The semiconductor package according to claim 6, wherein a wiring layer is disposed between the semiconductor substrate and the color filter.

9. The semiconductor package according to claim 1, wherein a flat region having the same height as an upper end of the on-chip lens is formed in a peripheral region around a pixel region in which pixels are arranged.

10. A method for manufacturing a semiconductor package, comprising:
a coating step of coating a resin on one surface of a glass substrate;
a curing step of curing the resin; and
a bonding step of bonding a surface of a wafer on which an on-chip lens is formed and the surface of the glass substrate on which the resin is coated.

11. The method for manufacturing a semiconductor package according to claim 10, wherein the bonding step includes bonding the wafer and the glass substrate by using surface energy therebetween.

12. The method for manufacturing a semiconductor package according to claim 10, further comprising a separating step of separating the wafer to which the glass substrate is bonded into individual semiconductor packages.
